(19) United States
(12) Patent Application Publication
(10) Pub. No.: US 2011/0101427 A1
(43) Pub. Date: May 5, 2011

(54) TRANSISTOR INCLUDING A HIGH-K METAL GATE ELECTRODE STRUCTURE FORMED PRIOR TO DRAIN/SOURCE REGIONS ON THE BASIS OF A SUPERIOR IMPLANTATION MASKING EFFECT

(76) Inventors: Thilo Scheiper, Dresden (DE); Andy Wei, Dresden (DE); Sven Beyer, Dresden (DE); Jan Hoentschel, Dresden (DE); Uwe Griebenow, Markkleeberg (DE)

(21) Appl. No.: 12/899,080

(22) Filed: Oct. 6, 2010

(30) Foreign Application Priority Data
Oct. 30, 2009 (DE) 10 2009 046 247.3

(51) Int. Cl. H01L 29/772; H01L 21/336

(52) U.S. Cl. 257/288; 438/285; 438/305; 257/E21.409; 257/E29.242

(57) ABSTRACT

When forming a sophisticated high-k metal gate stack in an early manufacturing stage, the dielectric cap layer may be efficiently removed without unduly affecting the drain and source extension regions. To this end, a specifically designed sidewall spacer structure may be used, such as a silicon dioxide spacer element in combination with a silicon nitride etch stop liner. The spacer structure may thus enable the removal of the dielectric cap layer while still maintaining the functions of an implantation mask and a silicidation mask during the further processing.

### BACKGROUND OF THE INVENTION

1. Field of the Invention

Generally, the present disclosure relates to the fabrication of highly sophisticated integrated circuits including transistor elements that comprise a high-k metal gate electrode structure formed in an early process stage.

2. Description of the Related Art

The fabrication of advanced integrated circuits, such as CPUs, storage devices, ASICs (application specific integrated circuits) and the like, requires a great number of circuit elements to be formed on a given chip area according to a specified circuit layout, wherein field effect transistors represent one important type of circuit element that substantially determines performance of the integrated circuits. Currently, a plurality of process technologies are practiced, wherein, for many types of complex circuitry, including field effect transistors, MOS technology is currently one of the most promising approaches due to the superior characteristics in view of operating speed and/or power consumption and/or cost efficiency. During the fabrication of complex integrated circuits using, for instance, MOS technology, millions of transistors, e.g., N-channel transistors and/or P-channel transistors, are formed on a substrate including a crystalline semiconductor layer. A field effect transistor, irrespective of whether an N-channel transistor or a P-channel transistor is considered, typically comprises so-called PN junctions that are formed by an interface of highly doped regions, referred to as drain and source regions, with a slightly doped or non-doped region, such as a channel region, disposed adjacent to the highly doped regions. In a field effect transistor, the conductivity of the channel region, i.e., the drive current capability of the conductive channel, is controlled by a gate electrode formed adjacent to the channel region and separated therefrom by a thin insulating layer. The conductivity of the channel region, upon formation of a conductive channel due to the application of an appropriate control voltage to the gate electrode, depends, among other things, on the dopant concentration, the mobility of the charge carriers and, for a planar transistor architecture, on the distance between the source and drain regions, which is also referred to as channel length.

Presently, the vast majority of integrated circuits are formed on the basis of silicon due to its substantially unlimited availability, the well-understood characteristics of silicon and related materials and processes and the experience gathered during the past 50 years. Therefore, silicon will likely remain the material of choice for future circuit generations designed for mass products. One reason for the importance of silicon in fabricating semiconductor devices has been the superior characteristics of a silicon/silicon dioxide interface that allows reliable electrical insulation of different regions from each other. The silicon/silicon dioxide interface is stable at high temperatures and, thus, allows the performance of subsequent high temperature processes, as are required, for example, for anneal cycles to activate dopants and to cure crystal damage without sacrificing the electrical characteristics of the interface.

For the reasons pointed out above, in field effect transistors, silicon dioxide is preferably used as a base material for gate insulation layers that separates the gate electrode, frequently comprised of polysilicon, from the silicon channel region. In steadily improving device performance of field effect transistors, the length of the channel region has been continuously decreased to improve switching speed and drive current capability. Since the transistor performance is controlled by, among other things, the voltage supplied to the gate electrode to invert the surface of the channel region to a sufficiently high charge density for providing the desired drive current for a given supply voltage, a certain degree of capacitive coupling, provided by the capacitor formed by the gate electrode, the channel region and the silicon dioxide disposed therebetween, has to be maintained. It turns out that decreasing the channel length for a planar transistor configuration requires an increased capacitive coupling in combination with sophisticated lateral and vertical dopant profiles in the drain and source regions to avoid the so-called short channel behavior during transistor operation. The short channel behavior may lead to an increased leakage current and to a pronounced dependence of the threshold voltage on the channel length. Aggressively scaled planar transistor devices with a relatively low supply voltage and thus reduced threshold voltage may suffer from an exponential increase of the leakage current due to the required enhanced capacitive coupling of the gate electrode to the channel region. Thus, the thickness of the silicon dioxide layer has to be correspondingly reduced to provide the required capacitance between the gate and the channel region. For example, a channel length of approximately 0.08 μm may require a gate dielectric made of silicon dioxide as thin as approximately 1.2 nm. Although usage of high speed transistor elements having an extremely short channel may typically be restricted to high speed applications, whereas transistor elements with a longer channel may be used for less critical applications, such as storage transistor elements, the relatively high leakage current caused by the direct tunneling of charge carriers through an ultra-thin silicon dioxide gate insulation layer may reach values for an oxide thickness in the range of 1-2 nm that may no longer be compatible with requirements for many types of circuits.

For this reason, new strategies have been developed in overcoming the limitations imposed by high leakage currents of extremely thin silicon oxide-based gate insulation layers. One very promising approach is the replacement of the conventional dielectric materials, at least partially, by dielectric materials having a dielectric constant that is significantly greater than the dielectric constant of silicon dioxide-based materials. For example, dielectric materials, also referred to as high-k dielectric materials, with a dielectric constant of 10.0 and significantly higher may be used, for instance in the form of hafnium oxide, zirconium oxide and the like. In addition to providing a high-k dielectric material in the gate insulation layers, appropriate metal-containing materials also may have to be incorporated since the required work function values for P-channel transistors and N-channel transistors may not be obtained on the basis of standard polysilicon gate materials. To this end, appropriate metal-containing materials may be provided so as to cover the sensitive high-k dielectric materials and act as a source for incorporating an appropriate metal species, such as lanthanum, aluminum and the like, in order to appropriately adjust the work function for N-channel transistors and P-channel transistors, respectively. Furthermore, due to the presence of a metal-containing conductive material, the generation of a depletion zone, as may typically occur in polysilicon-based electrode materials, may be substantially avoided. The process of fabricating a sophisticated gate electrode structure on the basis of a high-k dielectric material may require a moderately complex process sequence due to, for instance, the adjustment of an appropriate work function for the transistors of different conductivity type and the fact that high-k dielectric materials may typically be very sensitive when exposed to certain process conditions, such as high temperatures in the presence of oxygen and the like. Therefore, different approaches have been developed, such as providing the high-k dielectric material at an early manufacturing stage and processing the semiconductor devices with a high degree of compatibility with standard process techniques, wherein the typical electrode material polysilicon may be replaced in a very advanced manufacturing stage with appropriate metals for adjusting the work function of the different transistors and for providing a highly conductive electrode metal. While this approach may provide superior uniformity of the work function and thus of the threshold voltage of the transistors, since the actual adjustment of the work function may be accomplished after any high temperature processes, a complex process sequence for providing the different work function metals in combination with the electrode metal may be required. In other very promising approaches, the sophisticated gate electrode structures may be formed in an early manufacturing stage, while the further processing may be based on the plurality of well-established process strategies. In this case, the high-k dielectric material and any metal species for adjusting the work function may be provided prior to or upon patterning the gate electrode stack, which may comprise well-established materials, such as silicon and silicon/germanium, thereby enabling the further processing on the basis of well-established process techniques. On the other hand, the gate electrode stack and in particular the sensitive high-k dielectric materials in combination with any metal-containing cap layers may remain reliably confined by appropriate materials throughout the entire processing of the semiconductor device.

Further concepts for enhancing performance of transistors have been developed by providing a plurality of strain-inducing mechanisms in order to increase the charge carrier mobility in the channel regions of the various transistors. It is well known that charge carrier mobility in silicon may be efficiently increased by applying certain strain components, such as tensile and compressive strain for N-channel transistors and P-channel transistors, respectively, so that superior transistor performance may be obtained for an otherwise identical transistor configuration compared to non-strained silicon materials. For instance, efficient strain-inducing mechanisms may be implemented by incorporating a strained semiconductor material in the drain and source regions of transistors, for instance, in the form of a silicon/germanium alloy, a silicon/carbon alloy and the like, wherein the lattice mismatch between the semiconductor alloy and the silicon base material may result in a tensile or compressive state, which in turn may induce a desired type of strain in the channel region of the transistor. Other efficient strain-inducing mechanisms are well established in which a highly stressed dielectric material may be positioned in close proximity to the transistor, thereby also inducing a certain type of strain in the channel region.

Although the approach of providing a sophisticated high-k metal gate electrode structure in an early manufacturing stage, possibly in combination with additional strain-inducing mechanisms, may have the potential of providing extremely powerful semiconductor devices, such as CPUs, storage devices, systems on a chip (SOC) and the like, conventional approaches may still suffer from process non-uniformities, as will be described with reference to FIGS. 1a-1g.

FIG. 1a schematically illustrate a cross-sectional view of a semiconductor device 100 comprising a substrate 101, such as a silicon substrate, in combination with a semiconductor layer 102, such as a silicon layer or a semiconductor material comprising a significant amount of silicon. In the manufacturing stage shown, the semiconductor device 100 further comprises transistors 150A, 150B in an early manufacturing stage, which may be formed in and above an active region 102A and 102B, respectively. An active region is to be understood as a semiconductor region in the layer 102 in which PN junctions for one or more transistors are to be formed. An isolation structure 102C, such as a trench isolation, is provided in the semiconductor layer 102 and may laterally delineate active regions, such as the regions 102A, 102B. Furthermore, a plurality of gate electrode structures 160A, 160B and 160C may be formed above the semiconductor layer 102. In FIG. 1a, the gate electrode structures 160A, 160B are illustrated at a cross-section in which the gate electrode structures 160A, 160B are formed on the active regions 102A and 102B, respectively, wherein it should be appreciated that these gate electrode structures may extend beyond the corresponding active region, if required, and may thus be formed above a corresponding isolation region. For example, the gate electrode structure 160C may represent a corresponding portion of a gate electrode structure or may represent a conductive line or any other circuit element, such as a resistive structure and the like, which may have a similar configuration as the gate electrode structures 160A, 160B. As previously discussed, the gate electrode structures may comprise a gate insulation layer 161 formed on the active regions 102A and 102B, respectively, and may comprise a high-k dielectric material, such as hafnium oxide-based materials and the like. It should be appreciated that, frequently, a gate insulation layer 161 may additionally comprise a conventional dielectric material, such as a silicon oxide-based material, however, with a significantly reduced thickness of approximately 0.8 nm and less. Consequently, in total, the gate insulation layer 161 may have a thickness of 1.5 nm and more, while still providing an oxide equivalent thickness that may be 1 nm and less, while leakage currents may be significantly less compared to a conventional extremely thin silicon oxide-based material. Moreover, a metal-containing material may be formed on the gate insulation layer 161 and may have a different composition for transistors of different conductivity type. For example, a conductive cap layer 162A may be provided in the gate electrode structure 160A, while a conductive cap layer 162B may be applied in the gate electrode structure 160B. Typically, the gate electrode structure 160C may have one of the layers 162A, 162B. Moreover, an electrode material 163, such as silicon, silicon/germanium and the like, may be formed above the conductive cap layers 162A, 162B, respectively, followed by a dielectric cap layer 164, which is typically comprised of silicon nitride. Furthermore, a sidewall spacer structure 165, which may comprise a liner material 165A in combination with a spacer element 165B may be provided so as to protect the sidewalls of the electrode material 163 and in particular of the sensitive materials 162A, 161. The liner 165A and the spacer element 165B may typically be comprised of silicon nitride. As illustrated, the gate electrode structure 160B may have the materials 165A, 165B in the form of non-patterned layers in order to provide a growth mask for forming a strain-inducing semiconductor material 151 in the active region 102A so as to increase the charge carrier mobility in a channel region 152 of the transistor 150A.

As previously discussed, the semiconductor alloy 151, for instance provided in the form of a silicon/germanium alloy, may have a strained state and may thus induce a desired strain in the channel region 152. For instance, silicon/germanium may represent a very efficient strain-inducing source for P-channel transistors.

The semiconductor device 100 as illustrated in FIG. 1a may be formed on the basis of the following conventional process strategies. After forming the isolation region 102C and thus delineating the active regions 102A, 102B, appropriate materials for the gate insulation layer 161 and one of the layers 162A and 162B may be formed by any appropriate deposition technique. Thereafter, the conductive cap material may be appropriately patterned and the other one of the layers 162A, 162B is deposited, possibly followed by any heat treatments in order to appropriately diffuse a work function adjusting species towards the gate insulation layer 161. Prior to or after the corresponding adjustment of the work function, the electrode material 163, for instance in the form of silicon, may be deposited on the basis of well-established deposition techniques, followed by the deposition of the dielectric cap layer 164. Furthermore, additional materials, such as hard mask materials and the like, may be provided if required and thereafter a sophisticated lithography process and an anisotropic etch sequence may be performed in order to obtain the gate electrode structures 160A, 160B, 160C. During the patterning process, the dielectric cap layer 164 may thus provide superior efficiency of the patterning process and may also be used during the subsequent processing so as to encapsulate the electrode material 163 and the materials 162A, 161. As previously discussed, in sophisticated applications, a length of the gate electrode structures 160A, 160B, 160C, i.e., in FIG. 1a, a horizontal extension of the electrode material 163, may be 50 nm and less. Next, the materials 165A, 165B may be formed, for instance, by thermally activated chemical vapor deposition (CVD) techniques, plasma enhanced CVD techniques and the like, in order to form, in particular, the liner material 165A as a very dense silicon nitride material so as to reliably confine the sidewalls of the gate electrode structure. Thereafter, an etch mask may be provided to cover the transistor 150B in order to form the spacer elements 165B and possibly etch into the active region 102A in order to form corresponding cavities therein. During the corresponding etch process, the spacer structure 165 may substantially determine a lateral offset of the corresponding cavities with respect to the channel region 152. Next, a selective epitaxial growth process is performed in order to grow the strain-inducing semiconductor material 151. During a selective epitaxial growth process, process parameters are adjusted such that a significant material deposition on dielectric surface areas, such as the cap layers 164, the material 165B and the isolation region 102C, is substantially suppressed.

FIG. 1b schematically illustrates the semiconductor device 100 in a manufacturing stage in which an etch mask 103 covers the active region 102A and possibly the isolation region 102C, while exposing the gate electrode structure 160B and the active region 102B. Moreover, an etch process 104 is applied so as to obtain the spacer structure 165 on sidewalls of the gate electrode structure 160B. For this purpose, well-established plasma assisted etch recipes are applied. It should be appreciated that, during the etch process 104, a certain amount of material erosion in the active region 102B or material modification may occur, depending on the etch chemistry used. For example, plasma assisted etch recipes for removing silicon nitride may exhibit a self-limiting behavior when etching a silicon material, which may be caused by the generation of silicon dioxide, which may then act as an efficient etch stop material.

Thereafter, the etch mask 103 may be removed and thus the gate electrode structures 160A, 160B, 160C may have a substantially similar configuration, i.e., may comprise the sidewall spacer structure 165, which may be used as an offset spacer structure for controlling a subsequent implantation sequence for introducing dopant species so as to form drain and source extension regions and halo regions, i.e., counter-doped regions, in order to obtain the required complex dopant profile for adjusting the overall transistor characteristics. During the further processing, the dielectric cap layers 164 also have to be removed, which may, however, have a significant influence on the resulting device topography and thus on the resulting transistor characteristics. For instance, upon removing the dielectric cap material 164, plasma assisted etch chemistries are typically applied which, however, may also exhibit a significant lateral etch rate, thereby causing a significant degree of material erosion of the spacer structure 165. For this reason, the spacer structure 165 may be protected by providing a sacrificial spacer element having a superior etch resistivity, such as an oxide spacer.

FIG. 1c schematically illustrates the semiconductor device 100 with an oxide spacer layer 166, which may be etched during an etch process 105 in order to form sacrificial oxide spacers 166S on the sidewall spacer structure 165. Consequently, during the etch process 105, a certain degree of material erosion may occur in the isolation structure 102C, which may be substantially comprised of silicon dioxide material. Furthermore, any oxide material in the active region 102B which may be created during the previous silicon nitride etch process 104 (FIG. 1b) may also be removed, thereby possibly creating a certain degree of recessing (not shown).

FIG. 1d schematically illustrates the device 100 when exposed to a further etch process 106 for removing the dielectric cap material 164 (FIG. 1c). As discussed above, during the etch process 106, a certain degree of recessing or material conversion in the exposed portions of the active regions 102A, 102B may occur, as indicated by 102R, while, on the other hand, the silicon nitride spacer structure 165 is protected by the sacrificial spacer elements 166S.

FIG. 1e schematically illustrates the semiconductor device 100 in a further advanced manufacturing stage. As illustrated, the sacrificial sidewall spacers 166S (FIG. 1d) are removed, which may be accomplished on the basis of diluted hydrofluoric acid (HF), which, however, may also remove a portion of the isolation structure 102C, thereby increasing the recess 105R. Furthermore, any oxide material in the active regions 102A, 102B may also be removed, thereby creating the corresponding recesses 102R. Consequently, after the removal of the dielectric cap layer 164 (FIG. 1c), a pronounced surface topography in the form of the recesses 105R, 102R may be created, which may have a significant influence on the further processing.

FIG. 1f schematically illustrates the device 100 during an implantation sequence 107 in order to form drain and source extension regions 153E in the active region 102A. To this end, an implantation mask 108 is provided that covers the active region 102B. In the example shown, drain extension regions 153E are already formed in the active region 102B, possibly in combination with counter-doped regions or halo regions 153H, which may typically be required in sophisticated transistors in order to appropriately adjust transistor threshold and other transistor characteristics. During the implantation sequence 107, the recesses 102R may affect the resulting configuration of the extension regions 153E, as, for instance, the step-like shape of the active region 102A in the vicinity of the gate electrode structure 160A may result in a different penetration depth in the vicinity of the channel region 152. Furthermore, any halo regions to be formed on the basis of a tilted implantation process may require a reduced implantation energy due to the presence of the recess 102R, thereby also negatively affecting the resulting dopant profile in the vicinity of the channel region 152. It should be appreciated that similar negative effects may occur for the extension region 153E and the halo region 153H in the active region 102B. On the other hand, performing the implantation processes for forming the extension regions 153E and the halo regions 153H prior to removing the dielectric cap material 164 (FIG. 1c) may be a less attractive approach since, in this case, a significant amount of the extension dopants may be removed in the subsequent process sequence for removing the dielectric cap layer 164 due to the generation of the recesses 102R in close proximity to the channel region 152. In this case, additional implantation processes may be required so as to appropriately connect deep drain and source regions still to be formed with the reduced drain and source extension regions. In this case, additional lithography steps are required, thereby contributing to additional process complexity and overall manufacturing costs.

FIG. 1g schematically illustrates the semiconductor device 100 in a further advanced manufacturing stage. As illustrated, a further sidewall spacer structure 155 is formed adjacent to the spacer structure 165 and is typically comprised of silicon nitride, possibly in combination with a silicon dioxide etch stop liner (not shown). Furthermore, drain and source regions 153 are formed in the active regions 102A, 102B corresponding to the conductivity type of the transistors 150A, 150B. Furthermore, metal silicide regions 154 are formed in the drain and source regions 153 and metal silicide regions 167 are provided in the gate electrode structures 160A, 160B, 160C. Additionally, a dielectric layer 120, which may have a high internal stress level, is formed above the active regions 102A, 102B, the isolation region 102C and above the gate electrode structures 160A, 160B, 160C. As previously explained, a highly stressed dielectric material provided in the vicinity of a channel region of a transistor may represent an efficient strain-inducing mechanism, wherein the resulting amount of transistor performance enhancement may strongly depend on the internal stress level of the layer 120 and the amount of highly stressed material positioned in close proximity to the channel region 152, which in turn may thus depend on the thickness of the layer 120. Consequently, in view of enhancing transistor performance, an increased layer thickness is highly desirable for the layer 120, which, however, may be restricted by the pronounced surface topography, in particular in the isolation region 102C. That is, in device areas comprising closely spaced gate electrode structures extending along an isolation region, such as the region 102C, the pronounced recessing caused by the previous processing may additionally increase the resulting aspect ratio that is “seen” during the deposition of the material 120. Consequently, in view of the pronounced recessing of the isolation structure 102C, a reduced thickness of the layer 120 may have to be provided in order to avoid deposition-related irregularities, which may otherwise result in significant yield losses during the further processing, for instance when forming contact elements and the like.

The semiconductor device 100 as illustrated in FIG. 1g may be formed in accordance with the following process techniques. The spacer structure 155 is typically formed by depositing a silicon nitride material, possibly in combination with a silicon dioxide etch stop liner, and patterning the silicon nitride layer so as to obtain a spacer element, as shown. Based on the sidewall spacer structure 155, further implantation processes are performed in order to introduce further dopant species, thereby forming the drain and source regions 153. After any anneal processes in which the final dopant profile may be established, further cleaning processes are performed in order to prepare the exposed semiconductor surface areas for forming the metal silicide regions 154, 167. Typically, during any such cleaning processes, a further recessing in the isolation region 102C may be caused, thereby further contributing to a very pronounced surface topography. Thereafter, a silicidation process may be performed, wherein the spacer structure 155 may substantially determine the lateral offset of the metal silicide regions 154 with respect to the channel region 152. Next, the dielectric material 120 is deposited, wherein, depending on the process requirements, a complex deposition and patterning sequence may have to be applied when dielectric materials of different internal stress levels are to be provided above the transistor 150A and the transistor 150B. During the corresponding deposition process or processes, the pronounced surface topography has to be taken into consideration, as discussed above, thereby possibly reducing the efficiency of the strain-inducing effect of the dielectric material 120.

Consequently, although the conventional approach may provide high performance transistors on the basis of the high-k metal gate electrode structures 160A, 160B, 160C, less efficient dopant profiles or additional process complexity in forming the drain and source regions 153 may be obtained, in combination with a pronounced surface topography in the isolation region 102C may be caused, in particular due to the removal of the dielectric cap layer 164 (FIG. 1c).

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides semiconductor devices and manufacturing techniques in which a sophisticated high-k metal gate electrode structure may be provided in an early manufacturing stage. Furthermore, the further processing may be continued on the basis of an appropriately adapted spacer structure that enables the removal of a dielectric cap layer without negatively affecting the dopant profile of the drain and source extension regions and of halo regions in the vicinity of the channel region. At the same time, the spacer structure may maintain integrity of sensitive materials of the gate electrode structure upon removing the dielectric cap material. For this purpose, the spacer structure may be comprised of an appropriate material that may act as an etch stop material during the removal of the dielectric cap layer. Concurrently, the spacer structure may have an appropriate configuration so as to act as an implantation mask during the further processing for forming deep drain and source regions and to determine the desired offset of metal silicide regions to be formed in a later manufacturing stage. Consequently, by providing the spacer structure with appropriate dimensions to act as an implantation mask and a silicidation mask, any pronounced surface topography, such as recesses in active regions of semiconductor devices, may be offset from the channel region by the spacer width, thereby ensuring a desired dopant profile for the drain and source extension regions in the vicinity of the channel region, while a loss of dopants at the periphery of the drain and source regions may be readily compensated for during the regular deep drain and source implantation process.

One illustrative method disclosed herein comprises forming a gate electrode structure of a transistor above a semiconductor region of a semiconductor device. The gate electrode structure comprises a gate insulation layer comprising a high-k gate dielectric material, a metal-containing cap material formed on the gate insulation layer, an electrode material formed above the cap material, a dielectric cap layer formed above the electrode material and a first sidewall spacer structure. The method further comprises performing a first implantation process so as to form drain and source extension regions by using the gate electrode as a first implantation mask. Additionally, the method comprises forming a second sidewall spacer structure adjacent to the first sidewall spacer structure, wherein the second sidewall spacer structure comprises a spacer element. Moreover, the dielectric cap layer is removed by using the second sidewall spacer structure as an etch stop material for protecting the first sidewall spacer structure. Additionally, the method comprises performing a second implantation process to form drain and source regions by using the second sidewall spacer structure as a second implantation mask.

A further illustrative method disclosed herein relates to forming a transistor of a semiconductor device. The method comprises forming drain and source extension regions in an active region of the transistor by using a gate electrode structure as an implantation mask, wherein the gate electrode structure comprises a high-k dielectric material, an electrode material, a dielectric cap layer and a first sidewall spacer structure. The method further comprises forming a second sidewall spacer structure adjacent to the first sidewall spacer structure, wherein the second sidewall spacer structure comprises an etch stop liner and a spacer element. Moreover, the dielectric cap layer is removed selectively to the spacer element. Additionally, the method comprises forming drain and source regions by using the second sidewall spacer structure as an implantation mask.

One illustrative semiconductor device disclosed herein comprises a gate electrode structure formed on a semiconductor region. The gate electrode structure comprises a gate insulation layer including a high-k dielectric material, an electrode material and a sidewall spacer structure formed on sidewalls of at least a portion of the electrode material and on sidewalls of the gate insulation layer. The semiconductor device further comprises an etch stop liner comprising a first portion formed on the sidewall spacer structure and comprising a second portion that is formed on the semiconductor region and extends therefrom with a lateral distance. Additionally, the semiconductor device comprises a metal silicide region formed in a recessed portion of the semiconductor region, wherein a lateral offset of the recessed portion from the gate electrode structure substantially corresponds to the lateral distance.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1g schematically illustrate cross-sectional views of a semiconductor device comprising advanced transistors including a high-k metal gate electrode structure during various manufacturing stages, according to a conventional process strategy; and

FIGS. 2a-2g schematically illustrate cross-sectional views of a semiconductor device during various manufacturing stages in forming sophisticated transistor elements including a high-k metal gate electrode structure in combination with a sophisticated spacer structure, according to illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure provides semiconductor devices and manufacturing techniques in which confinement of sophisticated gate electrode structures may be accomplished on the basis of a first sidewall spacer structure, which may also provide a desired offset during the formation of source and drain extension regions and halo regions. Furthermore, a second sidewall spacer structure of appropriate configuration may be provided so as to be used as an efficient implantation mask for drain and source regions, while also enabling the removal of a dielectric cap material provided on the gate electrode material without negatively affecting the subsequent metal silicide process. That is, the second sidewall spacer structure is appropriately configured such that the masking effect during the drain and source implantation and during the metal silicide process is ensured, while at the same time the dielectric cap material may be removed on the basis of plasma assisted etch techniques without negatively affecting the drain and source extension profile and without unduly contributing to a pronounced surface topography.

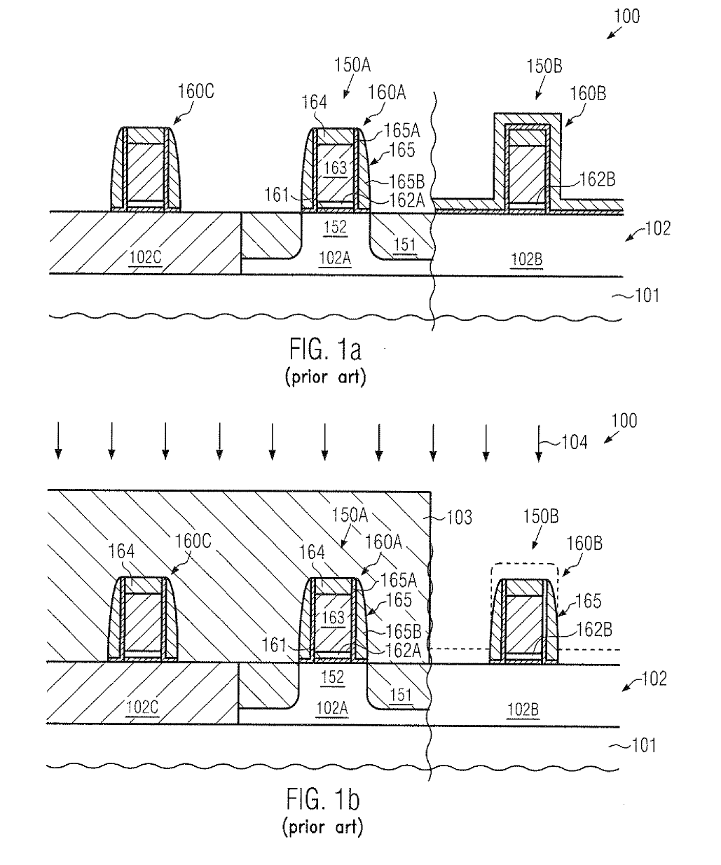

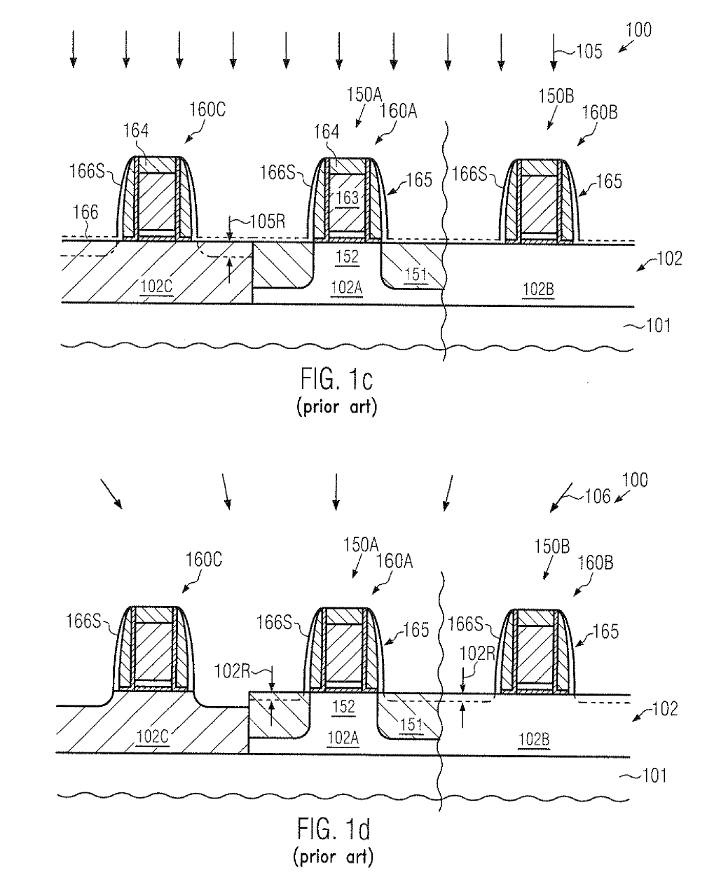

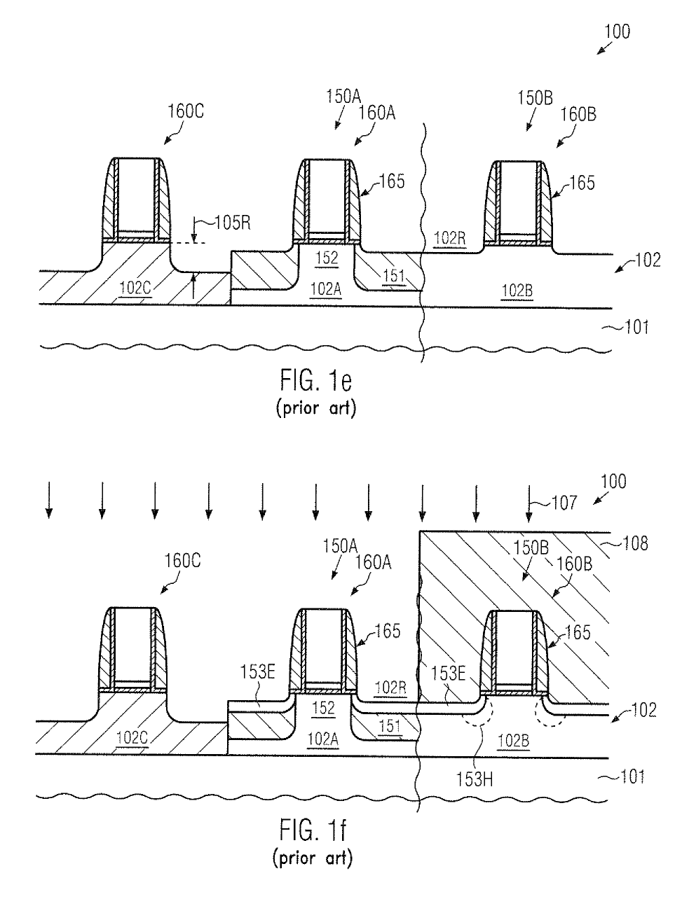

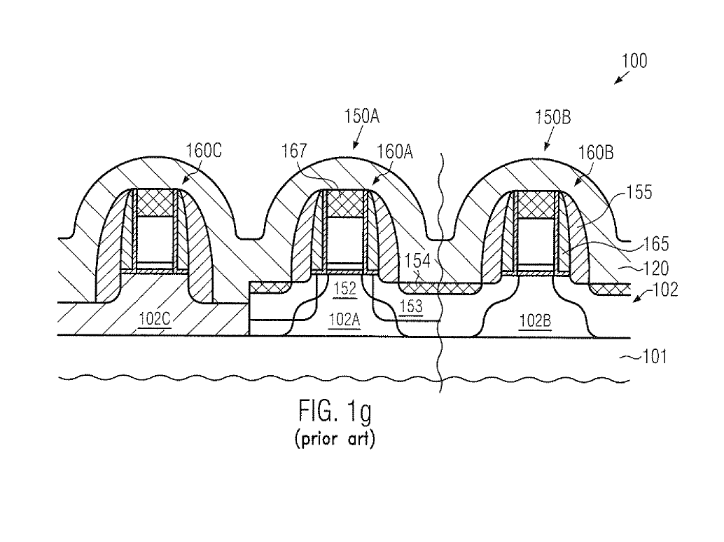

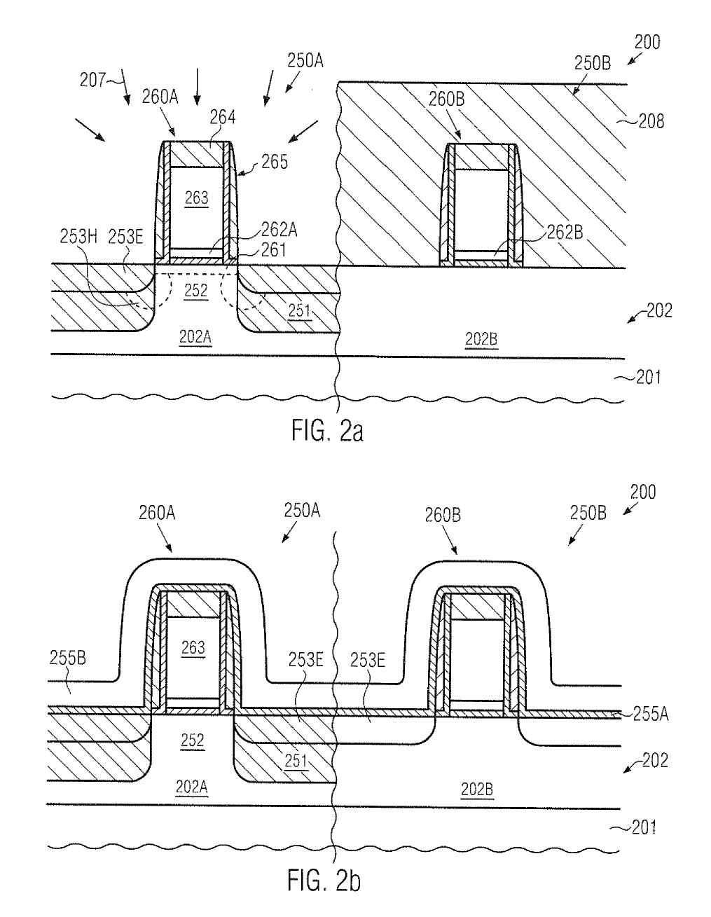

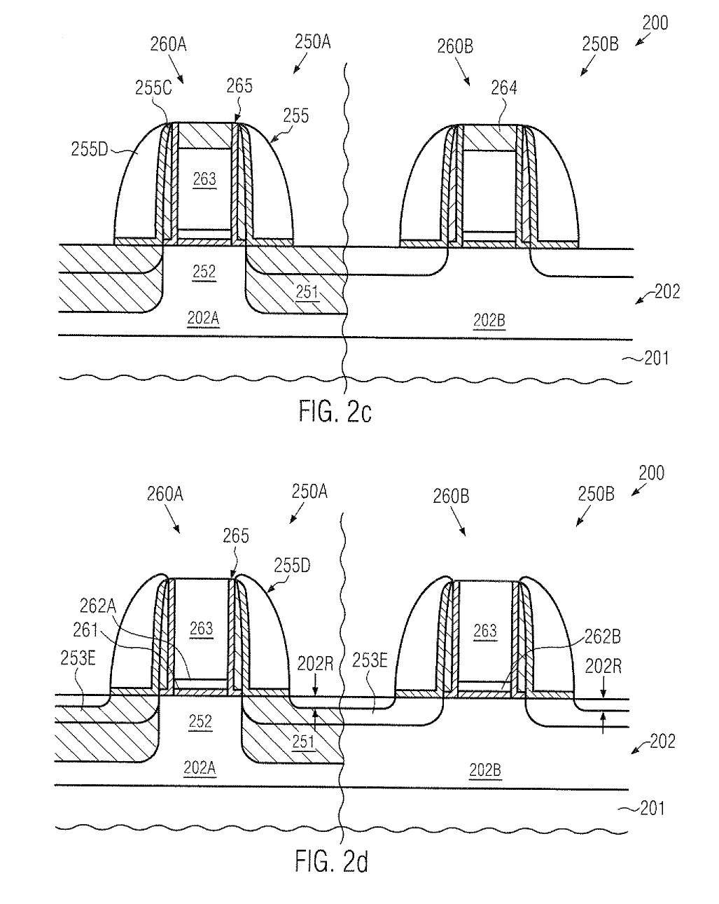

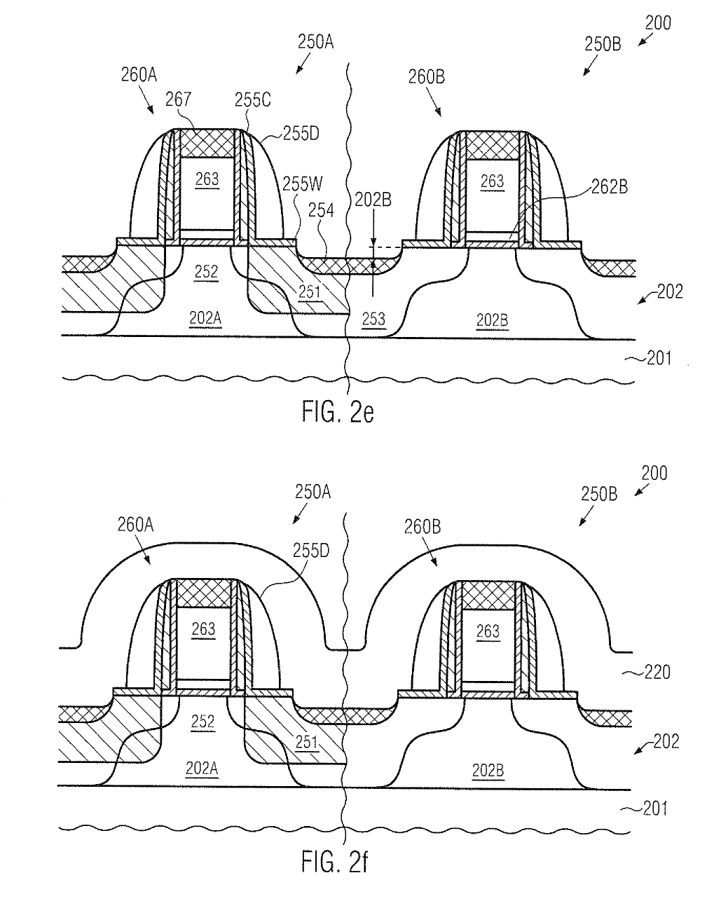

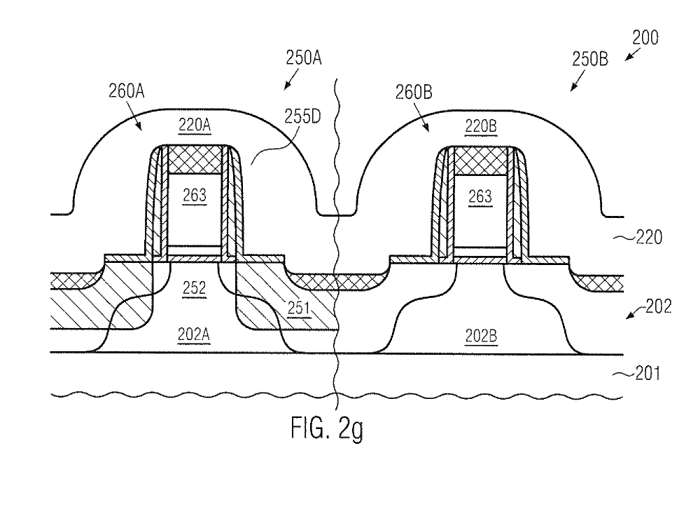

With reference to FIGS. 2a-2g, further illustrative embodiments will now be described, wherein reference may also be made to FIGS. 1a-1g, if appropriate.

FIG. 2a schematically illustrates a cross-sectional view of a semiconductor device 200 comprising a substrate 201 in combination with a semiconductor layer 202. The semiconductor layer 202 may represent a silicon-based material, a silicon/germanium material and the like. In some illustrative embodiments, a buried insulation layer (not shown) may be provided between the substrate 201 and the semiconductor layer 202 if a silicon-on-insulator (SOI) configuration may be considered appropriate. In other cases, the substrate 201 may represent a substantially crystalline semiconductor material. Moreover, in the semiconductor layer 202, active regions 202A, 202B may be provided, for instance may be laterally delineated by corresponding isolation structures, as is for instance described with reference to the semiconductor device 100. The active region 202A may correspond to a first transistor 250A, such as a P-channel transistor, while the active region 202B may represent a transistor 250B, such as an N-channel transistor. In the manufacturing stage shown, the transistor 250A may comprise drain and source extension regions 253E formed in the active region 202A laterally adjacent to a gate electrode structure 260A. Furthermore, counter-doped regions or halo regions 253H may be provided in accordance with device requirements so as to obtain the desired complex dopant profile in the vicinity of a channel region 252. In the example shown in FIG. 2a, the transistor 250B may comprise a gate electrode structure 260B wherein corresponding drain and source extension regions may not yet be formed in the active region 202B, while, in other cases, dopant species may already be incorporated, depending on the process strategy. Furthermore, in some illustrative embodiments, a strain-inducing mechanism on the basis of a strain-inducing semiconductor material may be implemented in one or both of the transistors 250A, 250B. In the embodiment shown, a semiconductor alloy 251 may be provided in the active region 202A, which may provide a compressive strain component if the transistor 250A may represent a P-channel transistor. In other cases, a tensile strain-inducing semiconductor material may be applied.

Moreover, in the manufacturing stage shown, the gate electrode structures 260A, 260B may have a similar configuration except for a metal-containing material system, which may provide the desired work function of the gate electrode structures 260A, 260B. That is, a gate insulation layer 261 may be provided in both gate electrode structures and may have substantially the same configuration except for any work function metal species that may have diffused into the material 261 during the preceding processing. In the gate electrode structure 260A, a metal-containing material layer 262A, which may also be referred to as a conductive cap layer, may be provided, followed by an electrode material 263, such as polysilicon, silicon/germanium and the like. Finally, a dielectric cap layer 264 may be formed on the electrode material 263. Furthermore, a sidewall spacer structure 265 may provide a reliable confinement of sensitive materials, such as the materials 261 and 262A. Similarly, the gate electrode structure 260B may comprise a metal-containing cap material 262B, which may differ from the material 262A in at least a work function adjusting species, while the remaining components may be the same as in the gate electrode structure 260A. It should be appreciated that the gate length of the structures 260A, 260B may be 50 nm or less, for example, approximately 32 nm in very sophisticated semiconductor devices.

The semiconductor device 200 as illustrated in FIG. 2a may be formed on the basis of the following processes. The active regions 202A, 202B and the gate electrode structures 260A, 260B may be formed on the basis of process techniques as are also previously described with reference to the semiconductor device 100. It should be appreciated that, if required, an appropriate adaptation of the work function may require a specifically designed semiconductor material in one of the active regions, for instance in the active region 202A, so as to obtain a desired band gap offset. For example, the transistor 250A may represent a P-channel transistor and a desired threshold voltage may be adjusted on the basis of a silicon/germanium alloy, which may be selectively formed in the active region 202A with an appropriate material composition and thickness.

After the patterning of the gate electrode structures 260A, 260B, an implantation mask 208 may be formed so as to cover the transistor 250B and expose the transistor 250A to an implantation sequence 207 in order to introduce the dopant species for the drain and source extension regions 253E and the halo regions 253H. As previously discussed, in other strategies, corresponding implantation regions may first be formed in the active region 202B, if considered appropriate. Thus, contrary to conventional approaches, as described above with reference to the device 100, the implantation process 207 may be performed on the basis of superior device topography since a significant recessing of the active region 202A may not have occurred since the dielectric cap layer 264 may still be present. Thus, a superior dopant profile may be obtained in the vicinity of the channel region 252, wherein increased implantation energies may be used for positioning the dopant species of the halo regions 253H within the active region 202A. Since the dielectric cap layer 264 is still present during the implantation 207, generally an increased implantation energy may be used for the halo implantation step, thereby achieving a superior distribution of the corresponding counter-doping species. In other illustrative embodiments, generally the height of the electrode material 263 and thus of the entire gate electrode structures 260A, 260B may be selected to be less compared to conventional approaches since the additional ion blocking capability of the dielectric cap layer 264 may ensure the required masking effect of the gate electrode structures. Consequently, by using a reduced gate height, the parasitic capacitance of the gate electrode structures 260A, 260B may be reduced.

After the implantation sequence 207, the mask 208 may be removed and an appropriate implantation sequence may be performed to form the drain and source extension regions and the halo regions for the transistor 250B, while the transistor 250A is appropriately masked. In other cases, the corresponding implantation sequence may have been performed prior to the implantation sequence 207.

FIG. 2b schematically illustrates the semiconductor device 200 in a further advanced manufacturing stage in which a spacer layer system including an etch stop liner 255A and a spacer layer 255B may be formed above the transistors 250A, 250B. In one illustrative embodiment, the spacer layer 255B may be comprised of a silicon dioxide material and the etch stop liner 255A may be comprised of silicon nitride. In other illustrative embodiments, any other appropriate material system may be provided, depending on the further processing. The spacer layer 255B may be provided with an appropriate thickness so as to obtain a spacer structure which may ensure the desired offset for forming drain and source regions and metal silicide regions in a subsequent manufacturing stage. The material layers 255A, 255B may be deposited on the basis of any appropriate deposition technique, such as plasma enhanced CVD, thermally activated CVD and the like.

FIG. 2c schematically illustrates the semiconductor device 200 in a further advanced manufacturing stage. As illustrated, the transistors 250A, 250B may comprise a second spacer structure 255 formed adjacent to the spacer structure 265. The spacer structure 255 may comprise an etch stop liner 255C which may represent the residues of the etch stop liner 255A (FIG. 2b). Furthermore, the structure 255 may comprise a spacer element 255D, i.e., the residues of the spacer layer 255B (FIG. 2b), wherein a width of the spacer structure 255 is appropriately selected so as to act as an implantation mask and provide a desired offset of metal silicide regions still to be formed. The spacer structure 255 as illustrated may be formed on the basis of an appropriate etch sequence in which the spacer layer 255B of FIG. 2b may be etched while using the liner 255A of FIG. 2b as an etch stop material. Thereafter, an exposed portion of the liner material 255A of FIG. 2b may be etched selectively with respect to the spacer element 255D, thereby obtaining the substantially L-shaped liner material 255C. For example, appropriate selective etch recipes for etching silicon dioxide selectively with respect to silicon nitride and for etching silicon nitride selectively with respect to silicon dioxide and silicon are available and may be applied for forming the spacer structure 255.

In some illustrative embodiments (not shown), the further processing may be continued by masking one of the transistors 250A, 250B and performing an implantation process in order to introduce dopant species for deep drain and source areas on the basis of the spacer structure 255. In this case, the dielectric cap layer 265 may still be in place and may thus provide a superior ion blocking effect of the gate electrode structures 260A, 260B. Consequently, also in this case, a high dopant concentration may be provided at an increased depth within the active regions without incorporating the dopant species into the channel region 252. After forming the drain and source regions in both transistors 250A, 250B, the further processing may be continued by removing the dielectric cap layer 264 on the basis of a plasma assisted etch process.

FIG. 2d schematically illustrates the semiconductor device 200 in an advanced manufacturing stage in which the dielectric cap layer 264 (FIG. 2c) may be removed prior to forming the drain and source regions in the transistors 250A, 250B. For this purpose, a plasma assisted etch process may be performed, such as a silicon nitride removal process, wherein the spacer element 255D may ensure integrity of the spacer structure 265 and thus of the sensitive materials 261, 262A and 262B. Due to the high etch selectivity, the width of the spacer element 255D may substantially remain unaffected by the corresponding removal process. Furthermore, any recessing or oxidizing effect 202R of the corresponding etch process may affect the active regions 202A, 202B at a position that is outwardly shifted away from the channel region 252 due to the presence of the spacer element 255D. Consequently, any loss of the dopant species in the drain and source extension regions 253E may be readily compensated for during the subsequent implantation for forming the drain and source regions. Thus, any additional implantation processes to appropriately connect the extension regions 253E to any deeper drain and source areas may not be required.

In some illustrative embodiments, the process sequence for forming the spacer structure 255 from the layer system 255A, 255B of FIG. 2b and the removal of the dielectric cap layer 264 of FIG. 2c may be performed as a substantially continuous etch sequence by first etching the layer 255B (FIG. 2b) on the basis of etch chemistry that has a high selectivity with respect to silicon nitride and thereafter changing the etch chemistry so as to etch silicon nitride material, thereby removing the cap layer 264 (FIG. 2c) and any exposed portion of the layer 255A (FIG. 2b). Furthermore, the etch process may be significantly slowed down due to a conversion of silicon in silicon dioxide material during the silicon nitride etch process, as previously explained. After the removal of the corresponding silicon oxide material, the recessing 202R may be generated during the further processing.

FIG. 2e schematically illustrates the semiconductor device 200 in a further advanced manufacturing stage. As shown, the transistors 250A, 250B may comprise drain and source regions 253 in combination with metal silicide regions 254. Similarly, metal silicide regions 267 may be formed in the gate electrode structures 260A, 260B. The drain and source regions 253 may be formed on the basis of implantation processes in which the spacer structure 255, as shown in FIG. 2d, in combination with the gate electrode structures 260A, 260B may act as an implantation mask, thereby ensuring the appropriate lateral offset during the implantation process. Moreover, as previously discussed, a dopant loss, which may be caused by removing the oxide material generated during the preceding silicon nitride etch process, may not negatively affect the finally obtained dopant profile of the drain and source regions 253. After any anneal processes for activating dopants, re-crystallizing implantation-induced damage and providing a certain degree of dopant diffusion, if desired, the device 200 may be prepared for the subsequent silicidation process sequence. For this purpose, cleaning processes may be performed in which silicon oxide materials may be attacked, thereby forming the recess 202B and also reducing the height and width of the spacer element 255D. Furthermore, material of isolation structures may be removed, however, to a significantly lesser degree compared to conventional strategies, since any pronounced material removal of the isolation structures in any preceding manufacturing stage may be substantially avoided. It should be appreciated that, during the corresponding cleaning processes, the etch stop liner 255C may not be substantially attacked and thus a horizontal portion 255W thereof may substantially maintain its width, thereby providing a desired lateral distance of the metal silicide regions 254 with respect to the channel region 252. Thereafter, an appropriate refractory metal may be deposited and may be heat treated so as to initiate a chemical reaction with underlying silicon material in accordance with well-established process techniques.

FIG. 2f schematically illustrates the semiconductor device 200 with a dielectric material 220 formed above the transistors 250A, 250B. The dielectric material 220 may be provided in the form of a silicon nitride-based material, possibly with a high internal stress level which may be different for the transistors 250A, 250B, as discussed previously with respect to the semiconductor device 100. Furthermore, the spacer element 255D may still be present, thereby, in total, reducing the parasitic capacitance of the gate electrode structures 260A, 260B due to a reduced dielectric constant of the spacer element 255D compared to conventional silicon nitride spacers.

It should be appreciated that the dielectric material 220 may be provided with an increased layer thickness, if desired, for instance in view of enhancing the overall stress transfer efficiency, when provided as a highly stressed dielectric material, since, in particular, a pronounced surface topography in isolation regions, as previously explained with reference to the device 100, may be reduced. Consequently, the aspect ratio between closely spaced gate electrode structures running over isolation regions may be less critical compared to the conventional strategy. With respect to forming the dielectric material 220, any appropriate process sequence may be applied so as to form a single continuous layer material or to form layer portions of different material characteristics, such as internal stress level and the like, above the transistors 250A, 250B.

FIG. 2g schematically illustrates the semiconductor device 200 according to still further illustrative embodiments in which the spacer element 255 (FIG. 2e) may be removed prior to the deposition of the dielectric layer 220. For this purpose, any appropriate etch recipe may be applied, such as diluted hydrofluoric acid, if the spacer element 255D is comprised of silicon dioxide. Consequently, upon depositing the dielectric material 220, an increased amount of material may be positioned more closely to the channel regions of the transistors 250A, 250B, thereby increasing the strain-inducing effect. For example, a layer portion 220A may have a high internal stress so as to enhance performance of the transistor 250A, while a second layer portion 220B may have an appropriate internal stress level so as to enhance performance of the transistor 250B.

As a result, the present disclosure provides semiconductor devices and manufacturing techniques in which the dielectric cap material of a high-k metal gate electrode structure may be removed without unduly affecting the dopant profile of the drain and source regions and in particular of drain and source extension regions and halo regions. For this purpose, a spacer structure may be provided which may act as an implantation mask and provide a desired lateral offset during the silicidation process, while at the same time enabling the reliable removal of the dielectric cap material. Consequently, a superior surface topography may be accomplished, while a reduced parasitic capacitance of the gate electrode structures and/or increased efficiency of a strain-inducing mechanism provided on the basis of a dielectric overlayer may also be accomplished.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a gate electrode structure of a transistor above a semiconductor region of a semiconductor device, said gate electrode structure comprising a gate insulation layer comprising a high-k gate dielectric material, a metal-containing cap material formed on said gate insulation layer, an electrode material formed above said cap material, a dielectric cap layer formed above said electrode material and a first sidewall spacer structure;
performing a first implantation process to form drain and source extension regions by using said gate electrode as a first implantation mask;
forming a second sidewall spacer structure adjacent to said first sidewall spacer structure, said second sidewall spacer structure comprising a spacer element;
removing said dielectric cap layer by using said second spacer structure as an etch stop material for protecting said first sidewall spacer structure; and
performing a second implantation process to form drain and source regions by using said second sidewall spacer structure as a second implantation mask.

2. The method of claim 1, wherein forming said second sidewall spacer structure comprises forming an etch stop liner above said first sidewall spacer structure, forming a spacer layer on said etch stop liner and etching said spacer layer selectively to said etch stop liner to form said spacer element and wherein said etch stop liner has a high chemical resistivity with respect to oxide removing cleaning chemistries.

3. The method of claim 1, wherein said etch stop liner comprises a silicon nitride based material.

4. The method of claim 1, wherein said first sidewall spacer structure and said dielectric cap layer comprise silicon nitride.

5. The method of claim 2, further comprising forming a metal silicide in said drain and source regions by using said etch stop liner as silicide mask.

6. The method of claim 1, further comprising forming a strain-inducing dielectric material above said drain and source regions and said gate electrode structure in the presence of at least a portion of said spacer element of said second sidewall spacer structure.

7. The method of claim 1, further comprising removing said spacer element and forming a strain-inducing dielectric material above said drain and source regions and said gate electrode structure after removal of said spacer element.

8. The method of claim 1, wherein said second implantation process is performed in the presence of said dielectric cap layer.

9. The method of claim 1, wherein said second implantation process is performed after removing said dielectric cap layer.

10. The method of claim 1, further comprising forming a strain-inducing semiconductor alloy in said semiconductor region in the presence of said gate electrode structure.

11. A method of forming a transistor of a semiconductor device, the method comprising:
forming drain and source extension regions in an active region of said transistor by using a gate electrode structure as an implantation mask, said gate electrode structure comprising a high-k dielectric material, an electrode material, a dielectric cap layer and a first sidewall spacer structure;
forming a second sidewall spacer structure adjacent to said first sidewall spacer structure, said second sidewall spacer structure comprising an etch stop liner and a spacer element;
removing said dielectric cap layer selectively to said spacer element; and
forming drain and source regions by using said second sidewall spacer structure as an implantation mask.

12. The method of claim 11, wherein said drain and source regions are formed prior to removing said dielectric cap layer.

13. The method of claim 11, further comprising forming a dielectric layer above said drain and source regions and said gate electrode structure in the presence of at least a portion of said spacer element.

14. The method of claim 11, further comprising removing said spacer element of said second sidewall spacer structure and forming a strain-inducing dielectric layer above said drain and source regions and said gate electrode structure.

15. The method of claim 11, further comprising forming a strain-inducing semiconductor alloy in said active region by using said dielectric cap layer and said first sidewall spacer structure as a growth mask.

16. The method of claim 11, wherein removing said dielectric cap layer comprises performing a plasma assisted etch process.

17. A semiconductor device, comprising:
a gate electrode structure formed on a semiconductor region, said gate electrode structure comprising a gate insulation layer including a high-k dielectric material, an electrode material and a sidewall spacer structure formed on sidewalls of at least a portion of said electrode material and on sidewalls of said gate insulation layer;
an etch stop liner comprising a first portion formed on said sidewall spacer structure and a second portion formed on said semiconductor region and extending with a lateral distance; and
a metal silicide region formed in a recessed portion of said semiconductor region, a lateral offset of said recessed portion from said gate electrode structure substantially corresponding to said lateral distance.

18. The semiconductor device of claim 17, further comprising a spacer element formed on said etch stop liner.

19. The semiconductor device of claim 17, further comprising a strain-inducing dielectric material formed on said etch stop liner.

20. The semiconductor device of claim 17, wherein said etch stop liner is comprised of silicon nitride material.
